(19) United States
(12) Patent Application Publication
(10) Pub. No.: US 2026/0182119 A1
(43) Pub. Date: Jun. 25, 2026

(54) LED PACKAGE WITH SIDE COATING AND METHOD OF MANUFACTURE

(71) Applicant: LUMILEDS LLC, San Jose, CA (US)

(72) Inventors: Walter DASCHNER, San Jose, CA (US); Grigoriy BASIN, San Jose, CA (US); Wouter SOER, Eindhoven (NL)

(73) Assignee: LUMILEDS LLC, San Jose, CA (US)

(21) Appl. No.: 18/989,665

(22) Filed: Dec. 20, 2024

(51) Int. Cl. H10H 29/80; H01L 25/075; H10H 29/01; H10H 29/85; H10H 29/851

(52) U.S. Cl. CPC H10H 29/8421; H10H 29/034; H10H 29/0361; H10H 29/0364; H10H 29/8512; H10H 29/857; H10H 29/942; H10W 90/00

(57) ABSTRACT

LED packages, wafers of LED dies and methods of manufacture are described. An LED package includes an LED die. The LED die includes a light-emitting semiconductor stack, which has a light-emitting top surface, a bottom surface opposite the light-emitting top surface, and at least one side surface. The light-emitting semiconductor stack is configured to emit pump light through the light-emitting top surface when powered on. First and second solder pads are disposed on the bottom surface of the light-emitting semiconductor stack and are electrically coupled to the semiconductor stack. A silicone wavelength converter is provided over the light-emitting top surface of the LED die. A first silicone material surrounds the side surfaces of the light-emitting semiconductor stack. A second silicone material is disposed under the LED die and surrounding the first and second solder pads. The second silicone material is harder than the first silicone material.

### BACKGROUND OF THE INVENTION

Chip-scale package (CSP) light-emitting diodes (LEDs) are a type of LED technology characterized by minimal packaging whereby the packaged LED die closely matches the size of the LED die itself. CSP LEDs, therefore, may significantly reduce the amount of space and material needed between the LED die and the light-emitting surface of the packaged LED die, making these LEDs incredibly compact. Such a small footprint may allow for a higher density of LEDs in a given area and provide greater flexibility in design, which is especially important in space-constrained applications.

Despite their diminutive size, CSP LEDs are highly efficient in both light output and heat dissipation. The reduction in packaging material may facilitate better thermal management, enhancing performance and potentially extending the lifespan of the LEDs. These LEDs are versatile enough for use in a broad range of applications, from mobile devices and automotive lighting to general lighting and electronic displays. Additionally, the streamlined production process of CSP LEDs makes them a cost-effective option, offering high performance without compromising on light quality or uniformity.

### SUMMARY OF THE INVENTION

LED packages, wafers of LED dies, and methods of manufacture are described. An LED package includes an LED die. The LED die includes a light-emitting semiconductor stack with a light-emitting top surface, a bottom surface opposite the light-emitting top surface, and at least one side surface. The light-emitting semiconductor stack is configured to emit pump light through the light-emitting top surface when powered on. First and second solder pads are disposed on the bottom surface of the light-emitting semiconductor stack and are electrically coupled to the semiconductor stack. A silicone wavelength converter is provided over the light-emitting top surface of the LED die. A first silicone material surrounds the side surfaces of the light-emitting semiconductor stack. A second silicone material is disposed under the LED die and surrounding the first and second solder pads. The first silicone material has a lower modulus than the first silicone material.

### BRIEF DESCRIPTION OF THE DRAWINGS

A more detailed understanding may be had from the following description, given by way of example in conjunction with the accompanying drawings, wherein like reference numerals in the figures indicate like elements, and wherein:

FIG. 1 is a cross-sectional view of an example CSP LED die;

FIG. 2 is a cross-sectional view of an example LED wafer;

FIG. 3 is a cross-sectional view of another example LED wafer;

FIG. 4 is a cross-sectional view of an example LED package;

FIG. 5 is a cross-sectional view of another example LED package; and

FIG. 6 is a flow diagram of an example method of manufacturing an LED package.

### DETAILED DESCRIPTION OF THE PREFERRED EMBODIMENTS

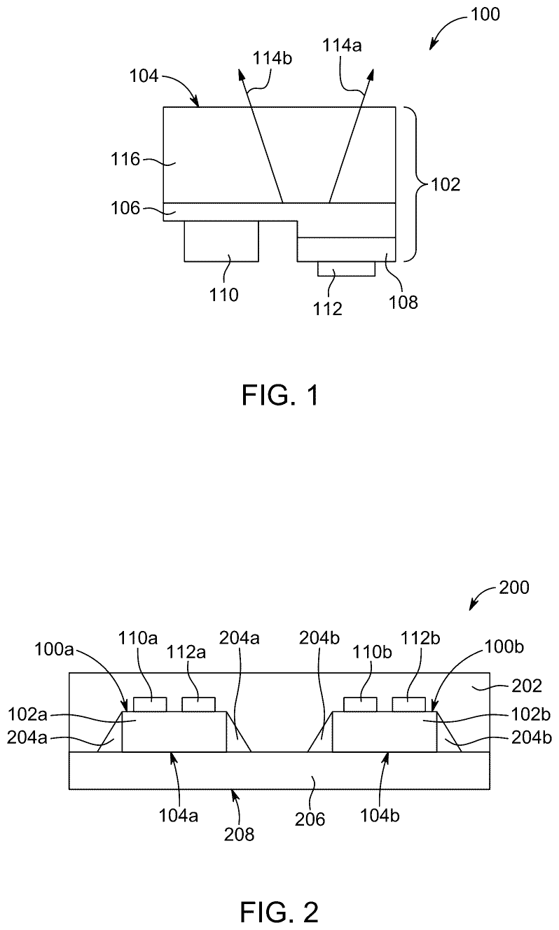

FIG. 1 is a cross-sectional view of an example CSP LED die 100. In the example illustrated in FIG. 1, the CSP LED die 100 includes a light-emitting semiconductor stack 102, which includes an n-type region 108, a p-type region 106 adjacent the n-type region 108, and a growth substrate 116. In some embodiments, for example, the n-type and p-type regions may be formed by growing them on the growth substrate 116, which may, in some embodiments, be formed from a sapphire material. The light-emitting semiconductor stack 102 may be formed from materials such as gallium arsenide or gallium nitride, chosen for their efficient light-emitting properties when electrified. While FIG. 1 shows a specific and basic structure for a light-emitting semiconductor stack, one of ordinary skill in the art will understand that the light-emitting semiconductor stack can be arranged differently with potentially more layers of various materials without departing from the scope of the embodiments described herein.

The CSP LED die 100 may also include solder pads 110 and 112 with the solder pad 110 being electrically coupled to the p-type region 106 and the solder pad 112 being electrically coupled to the n-type region 108. When powered on, the CSP LED die 100 emits pump light, which is represented by light rays 114a and 114b in FIG. 1 and which is emitted out of the CSP LED die 100 via the LED die light-emitting surface 104.

While not shown in FIG. 1, light rays can exit the LED die via any surface, including the bottom and side surfaces. Reflective surfaces and other optics may be used, some of which are described below, to ensure the majority of light exits the LED die via one or more desired surfaces (if needed for a particular application). Accordingly, in the embodiments described herein, the light-emitting top surface can be thought of as the surface through which it is desirable for the majority of light emitted by the LED die to exit the LED die.

In CSP LEDs, solder pads are small, conductive areas on the surface of the chip where solder may be applied to create electrical connections. These pads may be used for mounting the CSP LED onto a printed circuit board (PCB) or another substrate. They facilitate the transfer of electrical signals and power to the LED, enabling it to function.

Converters within packaged CSP LEDs provide color conversion and light quality enhancement. These converters may include phosphor particles, which utilize a process known as Stokes shift to absorb the pump light emitted from the LED die and re-emit it in a different color, effectively producing the capability for the CSP LEDs to be manufactured to emit light having one or more colors in a spectrum of hues from white light to specific colors tailored for diverse applications. The converter can be formed in advance of its deposition on a CSP LED die. Such a converter may be referred to as a converter platelet. Alternatively, one or more layers of converter material may be deposited directly onto the CSP die itself.

Silicone may be chosen as a matrix for converters due to its superior thermal stability, which is vital for maintaining performance under the high heat conditions typical of LED operation. Its flexibility and moldability also allow for precise control over the shape and thickness of the converter, optimizing light distribution and intensity. Furthermore, silicone's excellent optical properties ensure that light passes through with minimal loss, maximizing efficiency and brightness. These characteristics make silicone-based converter platelets integral to enhancing the functionality and applicability of CSP LEDs in fields such as general illumination, automotive lighting, and electronic display backlighting.

The manufacturing process for CSP LED dies typically begins with wafer fabrication (or growing a light-emitting semiconductor stack on a growth substrate). The wafer may then be subjected to various processing techniques, including, for example, photolithography, etching, and doping to create the structures essential for the LED's functionality. Following wafer processing, the wafer may be singulated into individual LED dies. Each die may then be packaged into an LED package that not only supports the die but also facilitates electrical connection and heat management. The LED die may then be encapsulated within its package using a protective resin, like silicone or epoxy, to safeguard against environmental damage and enhance the optical properties of the LED die. This comprehensive and streamlined process ensures the production of robust and efficient LEDs suitable for a wide range of lighting applications.

LED encapsulation involves covering the LED die with a protective material to safeguard it from environmental damage and physical impacts. Encapsulation serves primarily to protect the delicate semiconductor components of LEDs from moisture, dust, and other contaminants. This layer of protection may maintain the integrity and longevity of the LED, as exposure to harsh conditions can degrade materials and impair functionality.

In addition to protection, the encapsulation material may be selected for its optical properties. Common materials used include silicones and epoxies, which are transparent and can be tailored to enhance the light output of the LED. These materials help shape, diffuse, and sometimes convert the light, as seen in white LEDs where phosphor may be added to the encapsulant to change the color of the emitted light. This optical enhancement may improve the quality of the light output, making it suitable for a wide range of applications by reducing glare and distributing light more evenly.

Lastly, LED encapsulation may assist in thermal management and structural support. Though primarily for protection and optical adjustment, the encapsulant may help dissipate heat generated by the LED die, aiding in the overall thermal management system to maintain efficiency and prolong the die's lifespan. Additionally, the encapsulation may provide structural support for the die, and potentially delicate wire bonds, protecting these components during handling and operation. The encapsulation process may include filling or coating the LED package with an encapsulant material in a single deposition step, and the encapsulant may be cured through heating to form a durable seal.

In some embodiments, encapsulating may include applying a side coating on the LED package, which may involve applying a protective or functional layer around the sides of the LED package, which may enhance durability and performance. This coating shields the LED from environmental damage like moisture and dust, and prevents physical impacts and electrical failures. Additionally, it can be engineered to improve optical properties by enhancing light distribution and reducing glare. In some embodiments, for example, the encapsulating material, such as silicone, may be filled with reflective particles, such as TiO2, ZrO2, ZnO, Al2O3, to ensure that as much light as possible is converted and emitted from the LED package by helping to reflect light away from the LED or back into the converter to be converted. Some side coatings may also aid in thermal management by helping to dissipate heat from the LED die, maintaining optimal operating temperatures and extending the lifespan of the LED. This makes side coating a vital component in ensuring LEDs meet performance standards across various applications.

After encapsulation, grinding may be performed, for example to remove any encapsulant that may be left covering the solder pads after prior manufacturing processes. The grinding process can only be performed on a material that has hard enough (e.g., has a high enough modulus) to withstand grinding. If grinding is attempted on a material that does not have these properties, the softer material will not grind properly and will clog the wheel in addition to making shaping of the material more difficult.

Delamination of silicone (such as in the converter, the side coating, or other encapsulant) in CSP LEDs can stem from various environmental, material, and manufacturing challenges. One significant factor is thermal cycling, which causes materials to expand and contract at different rates due to their distinct thermal expansion coefficients. This may occur in LEDs during the normal course of operation due to LEDs being subjected to higher temperatures during operation and cooling back to room temperature when not in operation. This repeated stress, particularly between the silicone and the underlying semiconductor substrate, can weaken their bond, leading to delamination. Embodiments described herein, therefore, provide for LED wafers, LED packages, and corresponding methods of manufacture that may prevent silicone in the LED packages from delaminating, for example as a result of thermal cycling, while enabling the grinding process to be completed without damaging the LED die or the grinding wheel.

FIG. 2 is a cross-sectional view of an example LED wafer 200. In the example illustrated in FIG. 2, the LED wafer 200 includes two CSP LED dies 100a, 100b. Similar to the CSP LED die 100 of FIG. 1, each of the CSP LED dies 100a, 100b includes a light-emitting semiconductor stack 102a, 102b, a first solder pad 110a, 110b, and a second solder pad 112a, 112b. In the example illustrated in FIG. 2, a clear silicone fillet 204a, 204b is formed surrounding each of the CSP LED dies 100a, 100b to improve light extraction. While only two CSP LED dies are shown in FIG. 2, one of ordinary skill in the art will understand that an LED wafer can be made to include any number of LED dies without departing from the embodiments described herein.

A silicone wavelength converter platelet 206 is provided adjacent the light-emitting surface 104a, 104b of each of the CSP LED dies 100a, 100b, with the outer-most surface of the silicone wavelength converter platelet 206 being the light-emitting surface 208 of the LED wafer 200. The LED wafer 200 is filled with a silicone material 202.

In the example illustrated in FIG. 2, the silicone material 202 is applied in a single deposition step and cured, as mentioned above. A suitable silicone material 202 may be chosen for its ability to withstand harsh conditions, such as high temperatures and UV exposure. The silicone material 202 may be applied on lateral sides of the CSP LED dies 100a, 100b, encompassing exposed surfaces around the die and package. Various application methods such as dispensing, dipping, or spraying may be employed depending on the need for precision in thickness and uniformity.

In the process of LED manufacturing, the underside of the silicone material near the solder pads may require increased hardness and/or Young's modulus to facilitate the grinding process. This higher hardness and modulus may, however, generate stress on the converter platelet, which can be detrimental to the stability of the device. Selecting a single material, then, for the silicone material 202 used in the LED wafer 200 of in FIG. 2, for example, may result in either a device that cannot withstand the grinding process and/or delamination of the silicone wavelength converter platelet 206 from the CSP LED die 100a, 100b.

To mitigate this stress, in embodiments described herein, areas near and surrounding the converter platelet may be coated with a softer and/or lower modulus material to ensure long-term reliability. To optimize the coating's effectiveness and durability, the single-step side coat application may be replaced by a two-step process during which a higher modulus material is provided where robustness is essential and a lower modulus material may be provided in regions where stiffness could impair the LED's performance. This strategic approach may enhance the overall functionality and stability of the LED components, adapting to the specific mechanical demands of each area.

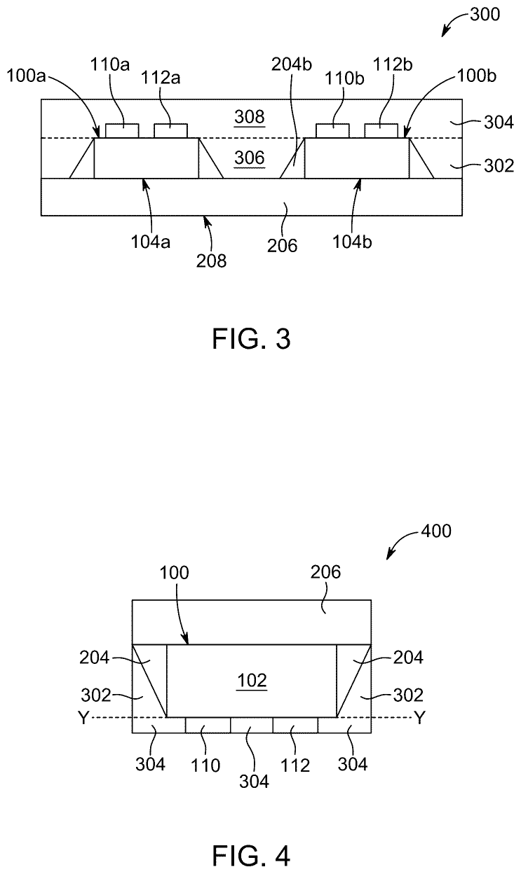

FIG. 3 is a cross-sectional view of another example LED wafer 300. In the example illustrated in FIG. 3, similar to the example LED wafer 200 illustrated in FIG. 2, the LED wafer 300 includes two CSP LED dies 100a, 100b. A silicone wavelength converter platelet 206 is provided adjacent the light-emitting surface 104a, 104b of each of the CSP LED dies 100a, 100b, with the outer-most surface of the silicone wavelength converter platelet 206 being the light-emitting surface 208 of the LED wafer 300.

In contrast to the LED wafer 200 illustrated in FIG. 2, the LED wafer 300 includes two regions of silicone material. A first region 306 is, as illustrated, immediately adjacent the silicone wavelength converter platelet 206 and comprises a first silicone material 302. A second region 308 is, as illustrated, immediately adjacent the first region 306 on the opposite side of the silicone wavelength converter platelet 206 and comprises a second silicone material 304. The first silicone material 302 may be a harder, higher modulus silicone material than the second silicone material 304, which may enable both grinding of the silicone material 304 and longevity of the CSP LED dies 100a, 100b by providing a harder, higher modulus material in the second region 308 near the solder pads 110a, 110b, 112a, 112b and a softer and lower modulus material in the first region 306 near the silicone wavelength converter platelet 206 to prevent or mitigate delamination.

In materials science, the term modulus refers to a measure that quantifies a material's stiffness or rigidity, indicating its ability to resist deformation under an applied force. The most common type is Young's Modulus, which measures the stiffness of a solid material in response to tensile stress. This modulus describes the relationship between stress (force per unit area) and strain (proportional deformation) in the linear elasticity range of a material and provides essential information about how a material will behave when stretched or pulled. Hardness is a measure of a material's resistance to deformation, particularly permanent deformation, indentation, or scratching.

Hardness and modulus, therefore, are related mechanical properties that describe a material's resistance to deformation, yet they focus on different types of deformation: hardness measures resistance to permanent (plastic) indentation, whereas modulus (typically Young's Modulus) quantifies stiffness or resistance to elastic deformation. Generally, materials that are hard also tend to exhibit higher moduli, as both properties are influenced by the strength of atomic or molecular bonds within the material. Understanding the relationship between these properties is crucial in material selection for applications requiring high wear resistance and minimal deformation, balancing these against other considerations such as ductility, toughness, and cost.

An example of a harder, higher modulus silicone material that may be used for the second silicone material 304 may be KMT-1872H silicone resin. Other similar silicone-based encapsulants, such as Dow Corning's EE-3200 or Wacker's SEMICOSIL® series, or similar materials, may alternatively be used for the second silicone material 304. These materials share common properties such as high transparency, thermal stability, and resistance to environmental factors, making them suitable for protecting and enhancing the performance of LED components.

Silicone resins, such as, or similar to, KMT-1872H, may be specifically engineered for LED encapsulation, safeguarding the components from environmental and physical impacts. They also boast superior optical properties with high transparency and stability under varying light and temperatures, ensuring the light emitted is not altered. These resins exhibit excellent thermal and environmental resistance, essential in LED applications prone to high heat. They also feature outstanding flow properties for uniform coverage without voids, and strong adhesion to various substrates, making KMT-1872H a reliable choice for enduring LED performance. One of ordinary skill in the art will, however, understand that other materials can be used that share similar properties without departing from the scope of the embodiments described herein.

An example of a softer, lower modulus silicone material that may be used for the first silicone material 302 may be Duroptix WR-3100 silicone resin. Other similar materials, such Dow Corning's EI-1184 and Wacker's LUMISIL® series, may alternatively be used for the first silicone material 302. These materials all offer high reflectivity, excellent thermal stability, and good mechanical properties, making them suitable for use in optoelectronics and semiconductor packaging where enhanced light output and protection against harsh conditions are highly desirable.

These silicone resins are particularly noted for their high reflectivity and are optimized for LED applications, achieving a reflectivity index of 98% at 450 nm. This makes these materials very suitable for use as the first silicone material 302 because a high reflectivity of material under and surrounding the CSP LED dies 100a, 100b may improve the overall light output of the resulting LED package. Duroptix WR-3100 silicone resin also has specific properties tailored for semiconductor applications, such as its curing condition and a mix ratio. It also features a hardness of score of D60 and an elongation percentage of 30%, allowing for a degree of flexibility in use. This material is also designed to be suitable for dispensing processes, for ease of application in industrial settings. One of ordinary skill in the art will, however, understand that other materials can be used that share similar properties without departing from the scope of the embodiments described herein.

A difference in hardness of the first and second silicone materials can be defined, in at least some embodiments, in terms of Shore hardness. By way of example, on the Shore A Durometer hardness scale, the second material can be defined as a silicone material classified as greater than Shore D60, and the first material can be defined as a silicone material classified as lower than Shore D60. One of ordinary skill in the art, however, will recognize how to select the first and second materials based on the examples described herein.

FIG. 4 is a cross-sectional view of an example LED package 400. In the example illustrated in FIG. 4, the LED package 400 includes a single CSP LED die 100, which may be produced at least in part by singulating the LED wafer 300 of FIG. 3. The single CSP LED die 100 may be surrounded on all sides by a clear silicone fillet 204 and is electrically coupled to solder pads 110 and 112, as described above. The LED package 400 may also include a portion of the silicone wavelength converter platelet 206 adjacent a surface of the CSP LED die 100 opposite the solder pads 110, 112.

The second silicone material 302 may surround the light-emitting semiconductor stack 102 and the clear silicone fillet 204 (if included). The silicone material 302a, 302b may include reflective particles, such as described above, and may extend from on or about the top of the solder pads 110, 112 (represented by the line X-X in FIG. 4) and may extend to a bottom surface of the silicone wavelength converter platelet 206 as shown in the drawing. As mentioned above, this may serve the dual purpose of creating a reflective surface surrounding the sides of the light-emitting semiconductor stack 102 and preventing the silicone wavelength converter platelet 206 from delaminating from the light-emitting semiconductor stack 102.

The first silicone material 304 may be provided below the light-emitting semiconductor stack 102 (e.g., under the line X-X), may surround the solder pads 110, 112, and may fill the space between the solder pads 110, 112. Similar to the second silicone material 302, the first silicone material may include reflective particles, such as described above. As mentioned above, this may serve the dual purpose of creating a reflective surface under the CSP LED die 100 and around the solder pads 110, 112 and enabling grinding of the first silicone material 302. In the example illustrated in FIG. 4, the portion of the silicone wavelength converter platelet 206 extends to the outer edges of the LED package 400.

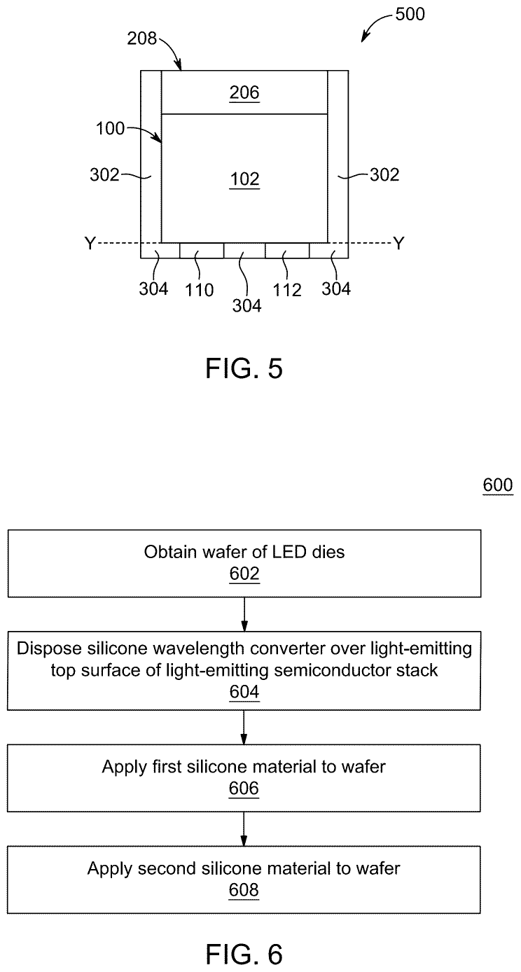

FIG. 5 is a cross-sectional view of another example LED package 500. In the example illustrated in FIG. 5, the LED package 500 includes a single CSP LED die 100, which may be produced at least in part by singulating an LED wafer (not illustrated). In the example illustrated in FIG. 5, the clear silicone fillet is omitted but could be included. The light-emitting semiconductor stack 102 of the CSP LED die 100 is electrically coupled to solder pads 110 and 112, as described above. The LED package 500 may also include a portion of the silicone wavelength converter platelet 206 adjacent a surface of the CSP LED die 100 opposite the solder pads 110, 112. In the example illustrated in FIG. 5, the portion of the silicone wavelength converter platelet 206 extends only to the lateral edges of the CSP LED die 100 and does extend to the lateral edges of the LED package 500.

The second silicone material 302 may surround the light-emitting semiconductor stack 102 (and the clear silicone fillet if included). The silicone material 302 may include reflective particles, such as described above, and may extend from on or about the top of the solder pads 110, 112 (represented by the line Y-Y in FIG. 5) and may extend to the light-emitting surface 208 of the LED package 500. As mentioned above, this may serve the dual purpose of creating a reflective surface surrounding the light-emitting semiconductor stack 102 as well as the silicone wavelength converter platelet 206 and preventing the silicone wavelength converter platelet 206 from delaminating from the CSP LED die 100. Extending the silicone material 302 to top of the LED package 500 may serve to prevent cross-talk between adjacent LED packages in an array, for example, preventing light converted by the silicone wavelength converter platelet 206 from entering an adjacent wavelength converter and being converted again and the adjacent LED emitting light having an undesired color.

The first silicone material 304 may be provided below the light-emitting semiconductor stack 102 (e.g., under the line Y-Y), may surround the solder pads 110, 112, and may fill the space between the solder pads 110, 112. Similar to the second silicone material 302, the first silicone material 304 may include reflective particles, such as described above. As mentioned above, this may serve the dual purpose of creating a reflective surface under the light-emitting semiconductor stack 102 and around the solder pads 110, 112 and enabling grinding of the first silicone material 304.

FIG. 6 is a flow diagram of an example method 600 of manufacturing an LED package. In the example illustrated in FIG. 6, a wafer of LED dies may be obtained (602). This may include purchasing the wafer or manufacturing it. The wafer of LED dies may be any of the wafer of LED dies described above and may include a light-emitting semiconductor stack, which may have a light-emitting top surface, a bottom surface opposite the light-emitting top surface, and at least one side surface. The light-emitting semiconductor stack may be configured to emit pump light through the light-emitting top when powered on. A first solder pad may be disposed on the bottom surface of the light-emitting semiconductor stack and electrically coupled to the semiconductor stack. A second solder pad may be disposed on the bottom surface of the light-emitting semiconductor stack and electrically coupled to the semiconductor stack.

A first silicone material may be applied to the wafer (604). This may be performed such that the first silicone material surrounds the side surfaces of the light-emitting semiconductor stack of each of the LED dies. A second silicone material may be applied to the wafer (606). This may be performed such that the second silicone material is disposed under the LED die of each of the plurality of LED dies and surrounding the side surfaces of the light-emitting semiconductor stack of each of the plurality of LED dies. The first silicone material has a lower modulus than the first silicone material.

The method illustrated in FIG. 6 may be a two-step process. For example, in a first step, the first silicone material may be dispensed followed by curing. In a second step, the second silicone material may be dispensed followed by curing. In some embodiments, the first silicone material may be completely cured before dispensing and curing the second silicone material. However, in other embodiments, the first and second silicone materials could be applied quickly (i.e., the second silicone material may be applied very quickly after the first silicone material is applied) and followed by a single curing step. The first and second silicone materials may be chosen based on any of the factors described above.

One or both of the first and second silicone materials can be filled with reflective particles before applying them to the wafer, as described in more detail above. The reflective particles can be, for example, one or more of TiO2 particles, ZrO2 particles, ZnO particles, or Al2O3 particles. The second silicone material may be grinded to expose the first and second solder pads from the second silicone material. The wafer may be singulated into individual LED dies. In some embodiments, a clear silicone fillet may be formed between the at least one side surface of each the LED dies and the first silicone material.

In the LED encapsulation process, various specialized tools may be utilized to ensure the precision and efficiency of encapsulating materials. Dispensing equipment plays a pivotal role, ranging from manual to automated systems, to apply encapsulants accurately. Additionally, molds and clamps may be employed to form the encapsulant around the LED die, tailored specifically to the LED die's dimensions and able to withstand the conditions of the curing process.

The encapsulation may also involve curing the materials applied to the LEDs, typically in ovens that provide controlled heat or UV light exposure to set the encapsulant properly. Post-application, the use of inspection systems, including advanced cameras and sensors, may become crucial to identify and rectify any defects, such as air bubbles or incomplete curing, ensuring the high quality and durability of the final product. In many instances, the encapsulation process may be performed by automated systems.

In the LED encapsulation process, automated dispensing equipment may be used. These systems may include time-pressure dispensers that control material release through timed air pressure, auger valve dispensers for precise handling of high-viscosity materials, and jet dispensers that can rapidly deploy small droplets at high frequencies. Additionally, robotic dispensing systems equipped with programmable arms may facilitate complex and varied encapsulation patterns, significantly enhancing both the speed and quality of production.

These system may automatically perform any of the methods described herein by executing instructions stored on one or more non-transitory computer-readable storage mediums. Examples of non-transitory computer-readable storage media include hard drives, solid-state drives (SSDs), CD-ROMs, DVDs, USB flash drives, and memory cards.

Having described the embodiments in detail, those skilled in the art will appreciate that, given the present description, modifications may be made to the embodiments described herein without departing from the spirit of the inventive concept. Therefore, it is not intended that the scope of the invention be limited to the specific embodiments illustrated and described.

What is claimed is:

1. A light-emitting diode (LED) package comprising:
an LED die comprising:
a light-emitting semiconductor stack comprising a light-emitting top surface, a bottom surface opposite the light-emitting top surface, and at least one side surface, wherein the light-emitting semiconductor stack is configured to emit pump light through the light-emitting top surface when powered on,
a first solder pad on the bottom surface of the light-emitting semiconductor stack and electrically coupled to the semiconductor stack, and
a second solder pad on the bottom surface of the light-emitting semiconductor stack and electrically coupled to the semiconductor stack;
a silicone wavelength converter over the light-emitting top surface of the LED die;
a first silicone material surrounding the side surfaces of the light-emitting semiconductor stack; and
a second silicone material under the LED die and surrounding the first and second solder pads, wherein the second silicone material is harder than the first silicone material.

2. The LED package of claim 1, wherein both the first silicone material and the second silicone material comprises reflective particles.

3. The LED package of claim 2, wherein the reflective particles are one or more of TiO2 particles, ZrO2 particles, ZnO particles, or Al2O3 particles.

4. The LED package of claim 1, wherein the first silicone material is one of a KMT-1872H silicone resin or Dow Corning's EE-3200 silicone resin and the second silicone material is one of Duroptix WR-3100H or Dow Corning EI-1184.

5. The LED package of claim 1, wherein the first silicone material has a Shore hardness of D60 or lower and the second silicone material has a Shore hardness of greater than D60.

6. The LED package of claim 1, further comprising a clear silicone fillet between the at least one side surface of the LED die and the first silicone material.

7. A wafer of light-emitting diodes (LEDs), the wafer comprising:
a plurality of LED dies, wherein each of the plurality of LED dies comprises:
a light-emitting semiconductor stack comprising a light-emitting top surface, a bottom surface opposite the light-emitting top surface, and at least one side surface, wherein the light-emitting semiconductor stack is configured to emit pump light through the light-emitting top when powered on,
a first solder pad on the bottom surface of the light-emitting semiconductor stack and electrically coupled to the semiconductor stack, and
a second solder pad on the bottom surface of the light-emitting semiconductor stack and electrically coupled to the semiconductor stack;
a silicone wavelength converter over the light-emitting top surface of each of the plurality of LED dies;
a first silicone material surrounding the side surfaces of the light-emitting semiconductor stack of each of the plurality of LED dies; and
a second silicone material under the LED die of each of the plurality of LED dies and surrounding the side surfaces of the light-emitting semiconductor stack of each of the plurality of LED dies, wherein the second silicone material is harder than the first silicone material.

8. The wafer of claim 7, wherein both the first silicone material and the second silicone material comprise reflective particles.

9. The wafer of claim 8, wherein the reflective particles are one or more of TiO2 particles, ZrO2 particles, ZnO particles, or Al2O3 particles.

10. The wafer of claim 7, wherein the first silicone material is one of a KMT-1872H silicone or Dow Corning's EE-3200 silicone resin and the second silicone material is one of Duroptix WR-3100H or Dow Corning EI-1184.

11. The wafer of claim 7, wherein the first silicone material has a Shore hardness of D60 or lower and the second silicone material has a Shore hardness of greater than D60.

12. The wafer of claim 7, further comprising a clear silicone fillet between the at least one side surface of each of the plurality of LED dies and the first silicone material.

13. A method of manufacturing an LED package, the method comprising:
obtaining a wafer of LED dies, wherein the wafer of LED dies comprises:
a light-emitting semiconductor stack comprising a light-emitting top surface, a bottom surface opposite the light-emitting top surface, and at least one side surface, wherein the light-emitting semiconductor stack is configured to emit pump light through the light-emitting top when powered on,
a first solder pad on the bottom surface of the light-emitting semiconductor stack and electrically coupled to the semiconductor stack, and
a second solder pad on the bottom surface of the light-emitting semiconductor stack and electrically coupled to the semiconductor stack;
disposing a silicone wavelength converter over the light-emitting top surface of the light-emitting semiconductor stack;
applying a first silicone material to the wafer such that the first silicone material surrounds the side surfaces of the light-emitting semiconductor stack of each of the plurality of LED dies; and
applying a second silicone material to the wafer such that the second silicone material is disposed under the LED die of each of the plurality of LED dies and surrounding the side surfaces of the light-emitting semiconductor stack of each of the plurality of LED dies, wherein the second silicone material is harder than the first silicone material.

14. The method of claim 13, further comprising selecting the first silicone material and the second silicone material.

15. The method of claim 14, wherein the first silicone material is selected to be one of a KMT-1872H silicone or Dow Corning's EE-3200 silicone resin and the second silicone material is selected to be one of Duroptix WR-3100H or Dow Corning EI-1184.

16. The method of claim 14, wherein the first material is selected to have a Shore hardness of D60 or lower and the second silicone material is selected to have a Shore hardness of greater than D60.

17. The method of claim 13, further comprising filling both the first silicone material and the second silicone material with reflective particles before applying the first and second silicone materials to the wafer.

18. The method of claim 17, wherein the reflective particles are one or more of TiO2 particles, ZrO2 particles, ZnO particles, or Al2O3 particles.

19. The method of claim 13, further comprising forming a clear silicone fillet between the at least one side surface of each of the plurality of LED dies and the first silicone material.

20. The method of claim 13, further comprising grinding the second silicone material to expose the first and second solder pads from the second silicone material.

21. The method of claim 13, further comprising singulating the wafer into individual LED dies.
